(19) United States
(12) Patent Application Publication
(10) Pub. No.: US 2015/0325789 A1
(43) Pub. Date: Nov. 12, 2015

(54) VARIABLE RESISTANCE MEMORY DEVICE AND METHOD OF FABRICATING THE SAME

(71) Applicant: SK hynix Inc., Icheon (KR)

(72) Inventors: Woo-Young PARK, Icheon (KR); Kwon HONG, Icheon (KR); Kee-Jeung LEE, Icheon (KR); Beom-Yong KIM, Icheon (KR)

(21) Appl. No.: 14/805,388

(22) Filed: Jul. 21, 2015

Related U.S. Application Data
(63) Continuation of application No. 13/846,655, filed on Mar. 18, 2013.

(30) Foreign Application Priority Data
Oct. 11, 2012 (KR) 10-2012-0112948

(51) Int. Cl. H01L 45/00

(52) U.S. Cl. CPC H01L 45/1616; H01L 45/1233; H01L 45/146; H01L 45/08; H01L 45/1641; H01L 45/1253

(57) ABSTRACT

Disclosed herein are a variable resistance memory device and a method of fabricating the same. The variable resistance memory device may include a first electrode; a second electrode; and a variable resistance layer configured to be interposed between the first electrode and the second electrode, wherein the variable resistance layer includes a Si-added metal oxide.

### CROSS-REFERENCE TO RELATED APPLICATIONS

The present application is a continuation of U.S. patent application Ser. No. 13/846,655 filed on Mar. 18, 2013, which claims priority of Korean Patent Application No. 10-2012-0112948, filed on Oct. 11, 2012, which are incorporated herein by reference in their entireties.

### BACKGROUND

1. Field

Exemplary embodiments of the present invention relate to a semiconductor technology, and more particularly, to a variable resistance memory device and a method of fabricating the same.

2. Description of the Related Art

Recently, a variety of variable resistance memory devices are developed which store data using variable resistance materials whose resistance state becomes different depending on an applied voltage or current.

Among a variety of variable resistance memory devices, a so-called ReRAM (Resistive Random Access Memory) is a device in which switching occurs when a filament including a current path is locally generated in or disappears from a variable resistance material layer made, for example, a metal oxide. In this case, since the generation/dissipation (or disappearance) of the filament is caused depending on a change in an oxygen vacancy in the metal oxide. The metal oxide having oxygen lower than a stoichiometry ratio may be used as a variable resistance material.

Meanwhile, as a degree of integration of a semiconductor device is recently increased, a variety of three-dimensional structures are developed in which memory cells are vertically stacked with respect to a substrate. Accordingly, the variable resistance memory device is also developed to have a three-dimensional structure. In order to fabricate the variable resistance memory device in the three-dimensional structure, there is a need to utilize a CVD (Chemical Vapor Deposition) method or an ALD (Atomic Layer Deposition) method having superior step coverage characteristics during a deposition of the variable resistance material layer.

In a case of utilizing such an ALD method or a CVD method, it is difficult to form a metal oxide layer having oxygen lower than the stoichiometry ratio as a variable resistance material.

Specifically, in the ALD method or the CVD method, the metal oxide layer is formed by a reaction of a metal organic precursor and oxygen. In this case, an amount of oxygen supplied as a reaction gas should be decreased in order to reduce the oxygen content of the metal oxide layer. In that case, however, a ligand of the metal organic precursor is not sufficiently removed, and carbon or oxygen remains within a layer as impurities, deteriorating layer characteristics. On the other hand, if the amount of oxygen supplied as a reaction gas is excessive, the resultant metal oxide layer becomes a material with the stoichiometry ratio which is not proper to serve as a variable resistance material layer.

### SUMMARY

Various embodiments are directed to provide a variable resistance memory device having superior switch characteristics while be able to realize a three-dimensional structure by a process improvement, and a method of fabricating the same.

In an embodiment, a variable resistance memory device includes a first electrode; a second electrode; and a variable resistance layer configured to be interposed between the first electrode and the second electrode, wherein the variable resistance layer includes a Si-added metal oxide.

In another embodiment, a variable resistance memory device includes a vertical electrode extending in a first direction perpendicular to a substrate; a plurality of horizontal electrodes stacked along the first direction and separated from each other; and a variable resistance layer configured to be coupled between the vertical electrode and at least one of the plurality of horizontal electrodes, wherein the variable resistance layer includes a Si-added metal oxide.

In still another embodiment, a method of fabricating a variable resistance memory device includes forming a first electrode; forming a variable resistance layer including a Si-added metal oxide and coupled to the first electrode; and forming a second electrode coupled to the variable resistance layer.

In a further embodiment, a method of fabricating a variable resistance memory device includes alternately stacking a plurality of interlayer insulating layers and a plurality of first patterns over a substrate; forming a hole penetrating the alternately-stacked structure to expose sidewalls of the plurality of first patterns; forming a variable resistance layer including Si-added metal oxide over a sidewall of the hole; and forming a vertical electrode in the hole.

### BRIEF DESCRIPTION OF THE DRAWINGS

FIG. 1 is a cross-sectional view illustrating a variable resistance memory device in accordance with an embodiment.

FIG. 2A is a cross-sectional view for explaining an example of a method of fabricating the device of FIG. 1, and FIG. 2B is a cross-sectional view for explaining another example of a method of fabricating the device of FIG. 1.

FIG. 3 is a view for explaining a method of forming a metal oxide atomic layer and a Si oxide atomic layer shown in FIG. 2A.

FIGS. 4A to 4F are cross-sectional views for explaining a variable resistance memory device and a method fabricating the same in accordance with another embodiment.

FIG. 5 is a cross-sectional view illustrating a variable resistance memory device in accordance with an embodiment.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

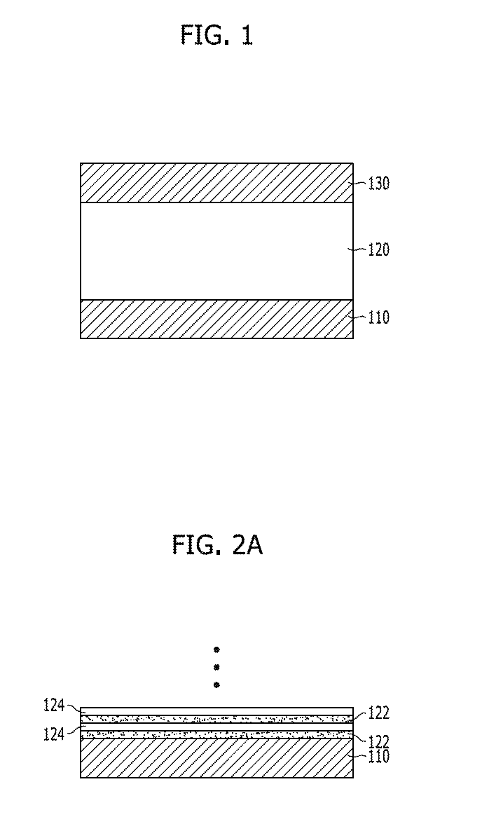

FIG. 1 is a cross-sectional view illustrating a variable resistance memory device in accordance with an embodiment.

Referring to FIG. 1, a variable resistance memory device according to an embodiment includes a first electrode 110, a second electrode 130, and a variable resistance layer 120 interposed therebetween.

The first and second electrodes 110 and 130 serve to apply voltage or current to the variable resistance layer 120. The first and second electrodes 110 and 130 may be made of a conductive material, for example, a metal such as platinum (Pt), tungsten (W), aluminum (Al), copper (Cu), and tantalum (Ta), or a metal nitride such as titanium nitride (TiN) and tantalum nitride (TaN).

The variable resistance layer 120 includes a Si-added metal oxide. The Si-added metal oxide may be, for example, Si-added Ti oxide, Si-added Ta oxide, Si-added Fe oxide, Si-added W oxide, Si-added Hf oxide, Si-added Nb oxide, Si-added Zr oxide, Si-added Ni oxide, Si-added Al oxide, Si-added La oxide, Si-added Mg oxide, Si-added Sr—Ti oxide, or a combination thereof, but the present invention is not limited thereto. Hereinafter, the metal oxide prior to Si addition is denoted as “MOy” (here, M refers to a metal and O refers to oxygen, y is a combination ratio between the metal and the oxygen) for convenience of description.

Here, the Si acts as a reducing agent of the metal oxide prior to Si addition (MOy). Specifically, the Si is bonded with oxygen of the metal oxide prior to Si addition (MOy) to remove the oxygen from the metal oxide prior to Si addition (MOy), thereby allowing an oxygen vacancy to be generated. Accordingly, when the metal oxide (MOy) is added with Si, the Si takes oxygen from the metal oxide (MOy) to form Si oxide. The remaining metal oxide after Si addition becomes MOx (0≦x<y) deficient in oxygen. That is, the Si-added metal oxide includes the metal oxide (MOx) having an oxygen ratio smaller than that of the metal oxide (MOy), and Si Oxide. Furthermore, the Si-added metal oxide may further include a bond of a metal (M) and Si, a bond of Si and oxygen, or a bond of a metal (M), Si, and oxygen.

As such, when the metal oxide (MOy) is added with Si, the metal oxide (MOy) is reduced due to the removal of oxygen therefrom. This is also indicated by the following chemical formulas.

For example, various chemical reactions occurring when the metal oxide (MOy) is tantalum (Ta) oxide and Si is added to the tantalum (Ta) oxide, may be illustratively indicated by the following chemical formulas (1) to (5) and the like.

(Ta₂O₅)+9(Si)=2(TaSi₂)+5(SiO) (1)

7(Ta₂O₅)+31(TaSi₂)=9(Ta₅Si)+35(SiO) (2)

(Ta₂O₅)+12(Ta₂Si)=31(Ta₂Si)+5(SiO) (3)

(Ta₂O₅)+17(Ta₂Si)=12(Ta₃Si)+5(SiO) (4)

(Ta₂O₅)+5(Ta₃Si)=17Ta+5(SiO) (5)

In accordance with the chemical formulas (1) to (5), when Si or TaSi is added to a tantalum oxide layer (Ta₂O₅), oxygen is removed from the tantalum oxide layer (Ta₂O₅) and bonded with the Si.

In addition, for example, various chemical reactions occurring when the metal oxide (MOy) is niobium (Nb) oxide and Si is added to the niobium (Nb) oxide may be illustratively indicated by the following chemical formulas (6) to (10) and the like.

(Nb₂O₅)+Si=2(NbO₂)+SiO (6)

(NbO₂)+4Si=(NbSi₂)+2(SiO) (7)

7(NbO₂)+13(NbSi₂)=4(Nb₅Si₃)+14(SiO) (8)

8(NbO₂)+Nb₅Si₃=13(NbO)+3(SiO) (9)

3(NbO)+Nb₅Si₃=8Nb+3(SiO) (10)

In accordance with the chemical formulas (6) to (10), when Si or NbSi is added to a niobium oxide layer (Nb₂O₅, NbO₂, or NbO), oxygen is removed from the niobium oxide layer (Nb₂O₅, NbO₂, or NbO) partly or entirely and bonded with the Si.

In short, when the metal oxide (MOy) is added with Si, oxygen is removed from the metal oxide (MOy) and an oxygen vacancy is generated at the place where the oxygen is removed. Likewise, when Si is added to the metal oxide (MOy) which satisfies a stoichiometry ratio, it may be possible to form a metal oxide having an oxygen ratio lower than the stoichiometry ratio. Accordingly, switching characteristics due to generation/dissipation of a filament may be shown if an oxygen vacancy is increased. Thus such metal oxide is suitable for a variable resistance material.

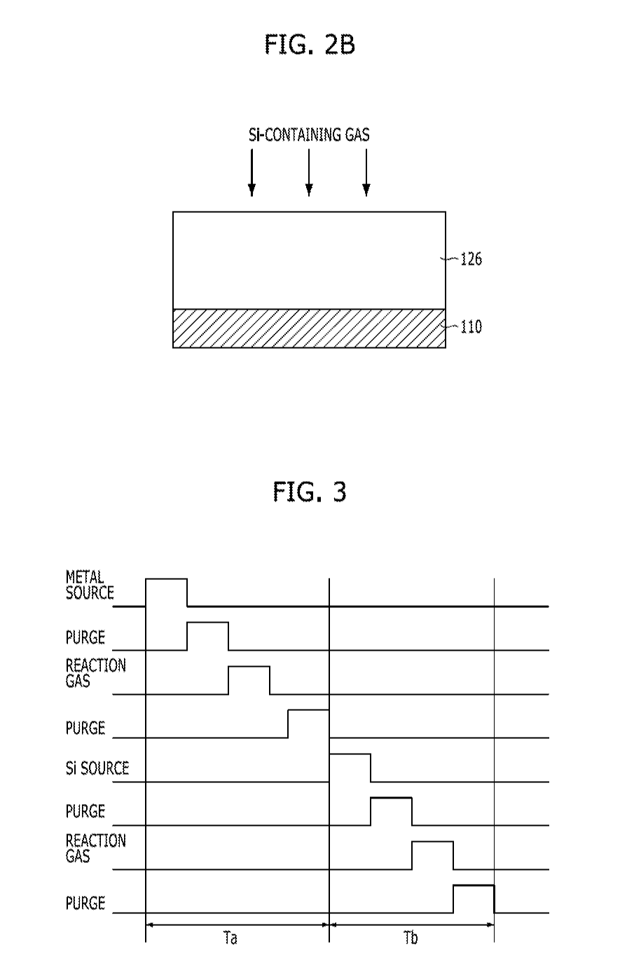

Hereinafter, a method of fabricating the device of IG. 1 will be described in detail with reference to FIGS. 2A to 3.

FIG. 2A is a cross-sectional view for explaining an example of the method of fabricating the device of FIG. 1.

Referring to FIG. 2A, the first electrode 110 is formed over a substrate (not shown) with a predetermined underlying structure.

Next, a plurality of metal oxide atomic layers 122 and a plurality of Si oxide atomic layers 124 are alternately formed over the first electrode 110 using an ALD method. The drawing shows two metal oxide atomic layers 122 and two Si oxide atomic layers 124, but the present invention is not limited thereto and more layers can be repeatedly formed. For example, the number of the metal oxide atomic layers 122 and Si oxide atomic layers 124 may be properly adjusted considering, for example, a target thickness of the variable resistance layer (see reference numeral 120 in FIG. 1).

Here, a method of forming the metal oxide atomic layers 122 and Si oxide atomic layers 124 will be described in more detail with reference to FIG. 3.

Referring to FIG. 3, one metal oxide atomic layer 122 may be formed by steps of: supplying a metal source, purging the metal source which is not adsorbed, supplying a reaction gas containing oxygen, for example, an O₃ gas, and purging the remaining (or surplus) reaction gas not involved in the reaction. In addition, any of Si oxide atomic layer 124 may be formed by steps of: supplying a Si source, purging the Si source which is not adsorbed (i.e., surplus of the Si source), supplying a reaction gas containing oxygen, and purging the reaction gas which is not reacted (i.e., surplus of the reaction gas). The formation cycle of one metal oxide atomic layer 122 is denoted as “Ta” and the formation cycle of one Si oxide atomic layer 124 is denoted as “Tb”. Ta+Tb may be repeated multiple times.

Here, the metal oxide atomic layer 122 may be, for example, a Ta₂O₅ layer satisfying the stoichiometry ratio by sufficiently supplying the reaction gas for an improvement in layer characteristics, but the present invention is not limited thereto. Alternatively, the metal oxide atomic layer 122 may be, for example, a TaOx layer (here, 0≦x<2.5) which does not satisfy the stoichiometry ratio. In addition, the Si oxide atomic layer 124 may be a SiO₂ layer satisfying the stoichiometry ratio, but the present invention is not limited thereto. For example, in another embodiment, the Si oxide atomic layer 124 may be a SiOx (0≦x<2) layer.

Returning to FIG. 2A again, when the metal oxide atomic layers 122 and the Si oxide atomic layers 124 are alternately stacked, the layers appear to be separated from each other. However, each atomic layer is an extremely thin layer of an atomic unit. Thus, each atomic layer may be regarded as a single layer where Si is uniformly distributed into the metal oxide layer 122. That is, for a convenience of description, an alternately-stacked structure of the metal oxide atomic layers 122 and the Si oxide atomic layers 124 may be represented by a single variable resistance layer 120, as shown in FIG. 1. For example, when each metal oxide atomic layer 122 is a Ta₂O₅ layer, the variable resistance layer 120 is a Ta₂O₅ layer with Si (or a Si-containing Ta₂O₅ layer) which may include TaOx (here, 0≦x<2.5), TaSi₂, SiO, and the like.

Subsequently, although not shown in the drawing, a heat treatment or a plasma treatment may be further performed in a gas atmosphere containing hydrogen, for example, an H₂ or NH₃ gas atmosphere to promote a reduction reaction of TaOx using Si.

Next, referring to FIG. 1 again, the device of FIG. 1 may be fabricated by forming the upper electrode 130 over the variable resistance layer 120.

FIG. 2B is a cross-sectional view for explaining another example of the method of fabricating the device of FIG. 1.

Referring to FIG. 2B, the first electrode 110 is formed over a substrate (not shown) formed with a predetermined underlying structure.

Next, a metal oxide layer 126 is formed over the first electrode 110. The metal oxide layer 126 may be formed by an ALD method or a CVD method. In this case, the metal oxide layer 126 may be, for example, a Ta₂O₅ layer satisfying the stoichiometry ratio which can be formed by sufficiently supplying the reaction gas for an improvement in layer characteristics, but the present invention is not limited thereto. For instance, the metal oxide layer 126 may also be, for example, a TaOx layer (here, 0≦x<2.5) which does not satisfy the stoichiometry ratio.

Subsequently, the metal oxide layer 126 is treated with a Si-containing gas. The Si-containing gas may be, for example, a SiH₄ or Si₂H₆ gas, but the present invention is not limited thereto.

When the metal oxide layer 126 is treated with the Si-containing gas, the metal oxide layer 126 is added with Si and thus the variable resistance layer 120 of FIG. 1 may be formed. For example, when the metal oxide layer 126 is a Ta₂O₅ layer, the variable resistance layer 120 is a Ta₂O₅ layer with Si and may include TaOx (here, 0≦x<2.5), TaSi₂, SiO, and the like.

Subsequently, although not shown in the drawing, a heat treatment or a plasma treatment may be further performed in a gas atmosphere containing hydrogen, for example, an H₂ or NH₃ gas atmosphere to promote a reduction reaction of the metal oxide layer 126 with Si.

Next, referring to FIG. 1 again, the device of FIG. 1 may be fabricated by forming the upper electrode 130 over the variable resistance layer 120.

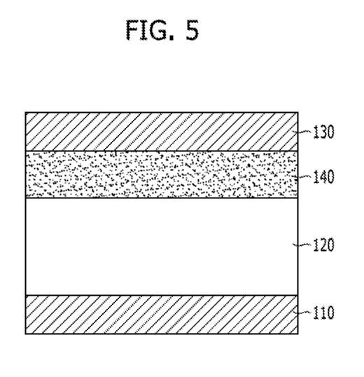

Meanwhile, another metal oxide layer 140 may also be further included between the first electrode 110 and the variable resistance layer 120 or between the second electrode 130 and the variable resistance layer 120 in order to supply an oxygen vacancy to the variable resistance layer 120 (see FIG. 5). The other metal oxide layer 140 may be a metal oxide layer, for example, a TiOx (here, 0≦x<2.0) or TaOx (here, 0≦x<2.5) layer which does not satisfy the stoichiometry ratio, but the present invention is not limited thereto.

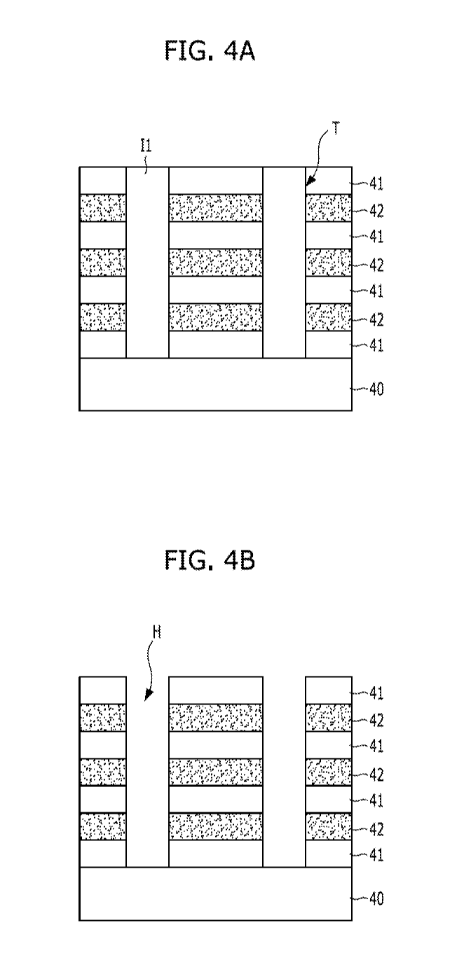

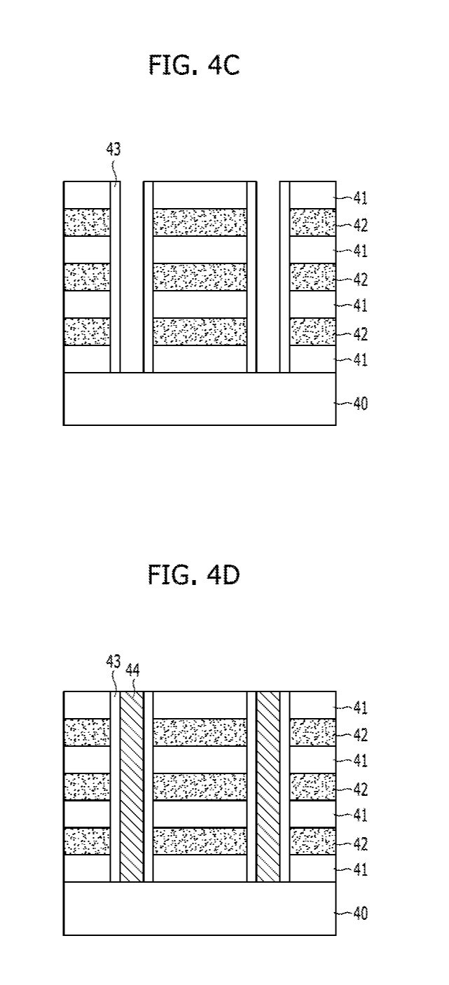

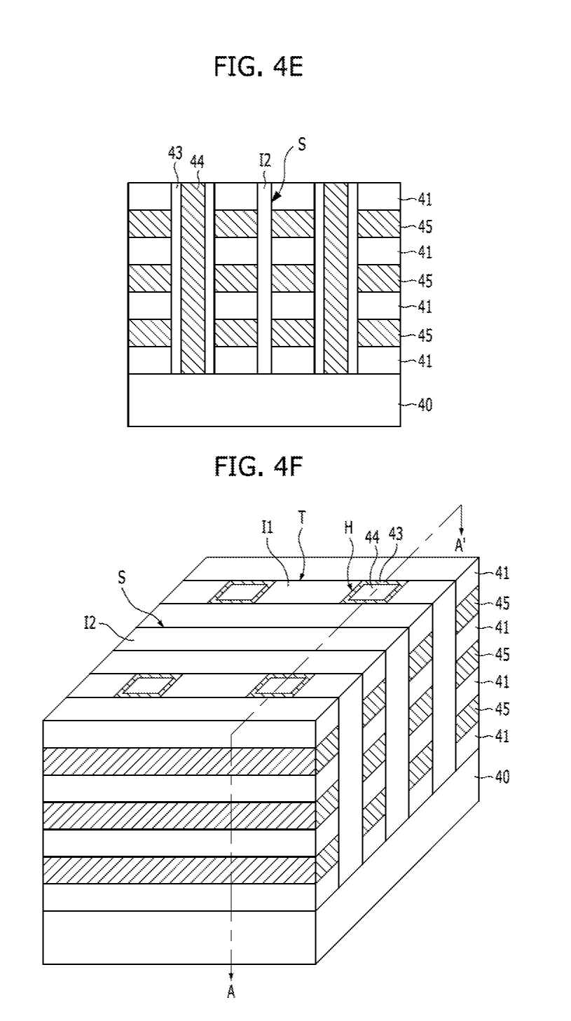

FIGS. 4A to 4F are cross-sectional views for explaining a variable resistance memory device and a method fabricating the same in accordance with another embodiment. FIGS. 4E and 4F show the device, and FIGS. 4A to 4D show an example of an intermediate process step for fabricating the device of FIGS. 4E and 4F. In addition, FIGS. 4A to 4E are shown based on a cross section taken along line A-A′ of FIG. 4F. The variable resistance memory device of the present embodiment has a three-dimensional structure in which unit memory cells are stacked in a vertical direction from a substrate.

Referring to FIG. 4A, a plurality of interlayer insulating layers 41 and a plurality of sacrifice layers 42 are alternately stacked over a substrate 40 having a predetermined underlying structure.

The plural sacrifice layers 42 are replaced with horizontal electrodes in the follow-up process, and may include, for example, nitride layers having an etching selectivity different from that of the interlayer insulating layers 41. The interlayer insulating layers 41 insulate the plural horizontal electrodes from each other, and may include oxide layers, for example.

Next, trenches T in a line pattern which extend in a direction intersecting with line A-A′ (hereinafter, referred to as “first direction”) are formed by selectively etching the alternately-stacked structure of the interlayer insulating layers 41 and sacrificial layers 42, and then filled with first insulating materials I1. The stacked structure may be divided into two separate structures by the trench T.

Referring to FIG. 4B, holes H exposing side walls of the sacrificial layers 42 are formed by selectively etching the first insulating materials I1. Each of the holes H defines a region in which a variable resistance layer and a vertical electrode which will be described later are formed.

Referring to FIG. 4C, a variable resistance layer 43 is formed over a side wall of the hole H so as to extend over the plurality of sacrificial layers 42. In this case, the variable resistance layer 43 may be formed using the above-mentioned process of FIG. 2A or 2B.

Specifically, metal oxide atomic layers and Si oxide atomic layers are alternately stacked using, for example, an ALD method over an entire surface of the resultant product including a sidewall of the hole H until the stack of the metal oxide atomic layers and the Si oxide atomic layers reaches a desired thickness. The variable resistance layer 43 is removed except that over the sidewall of the hole H by performing a dry etching process.

Alternatively, a metal oxide layer having a desired thickness is formed using an ALD or CVD method over an entire surface of the resultant product including a sidewall of the hole H. The variable resistance layer 43 may be formed over the sidewall of the hole H by treating the metal oxide layer with a gas containing hydrogen and performing a dry etching process.

In a case of using the process of FIG. 2A or 2B, even though an aspect ratio of the hole H is great, the variable resistance layer 43 is satisfactorily formed if an ALD or CVD method is employed which has superior step coverage characteristics. Consequently, the process may be easily performed. In addition, the variable resistance layer 43 including an oxygen vacancy created by the reduction using Si may improve switching characteristics of the variable resistance memory device.

Although not shown, after the variable resistance layer 43 is formed, a heat or plasma treatment process may be further performed in a gas atmosphere containing hydrogen.

Referring to FIG. 4D, a vertical electrode 44 which extends in a direction perpendicular to the substrate 40 is formed by filling a conductive material in the hole H in which the variable resistance layer 43 is formed. The vertical electrode 44 corresponds to any one of the first and second electrodes 110 and 130 of FIG. 1.

Referring to FIGS. 4E and 4F, a slit S which has a depth penetrating at least plural sacrificial layers 42 is formed between two neighboring vertical electrodes 44 by selectively etching the alternately-stacked structure of the interlayer insulating layers 41 and the sacrificial layers 42. The slit S serves, in a subsequent process, as a conduit along which a wet etchant for removing the sacrifice layers 42 is provided, and may extend in the first direction.

Next, the sacrificial layers 42 exposed by the slit S are removed by a wet etching process. Horizontal electrodes 45 which are disposed in parallel with the substrate 40 are formed by filling a conductive material in a space created by a removal of the sacrificial layers 42. The horizontal electrodes 45 correspond to any of the first and second electrodes 110 and 130 shown FIG. 1.

Subsequently, the slit S is filled with a second insulating material 12.

The variable resistance memory device in FIGS. 4E and 4F is fabricated by the above-mentioned processes.

In the variable resistance memory device, each of the unit memory cells includes one vertical electrode 44, one horizontal electrode 45, and the variable resistance layer 43 coupled to the vertical and the horizontal electrodes 44, 45.

Meanwhile, although not shown, the above-mentioned processes of FIGS. 4A to 4F may also be deviated from as follows. In the process of FIG. 4A, conductive layers for horizontal electrode may also be directly deposited without a process of forming the sacrificial layers 42. In this case, it may be possible to omit the process which replaces the sacrificial layers 42 with the horizontal electrodes 45.

In addition, although not shown, it may be possible to omit the process of forming the trenches T and the process of forming the first insulating materials I1. In this case, the holes H are directly formed by selectively etching the alternately-stacked structure of the interlayer insulating layers 41 and the sacrificial layers 42, instead of selectively etching the first insulating material I1. Thus, a unit memory cell includes one vertical electrode 44, one horizontal electrode 45, and the variable resistance layer 43 coupled to the vertical and the horizontal electrodes 44, 45.

In addition, although not shown, in the above-mentioned device of FIGS. 4E and 4F, another metal oxide layer to supply an oxygen vacancy may be further included between the horizontal electrode 45 and the variable resistance layer 43 or between the vertical electrode 44 and the variable resistance layer 43.

In accordance with a variable resistance memory device and a method of fabricating the same, it may be possible to have superior switch characteristics while enhancing an integration degree through a three-dimensional structure.

Although various embodiments have been described for illustrative purposes, it will be apparent to those skilled in the art that various changes and modifications may be made without departing from the spirit and scope of the invention as defined in the following claims.

What is claimed is:

1. A method of fabricating a variable resistance memory device, comprising:
forming a first electrode;
forming a variable resistance layer including a Si-added metal oxide and coupled to the first electrode; and
forming a second electrode coupled to the variable resistance layer.

2. The method of claim 1,
wherein the forming of the variable resistance layer comprises:
forming a metal oxide atomic layer using ALD (Atomic Layer Deposition); and
forming a Si oxide atomic layer using ALD, and
repeating the step of forming of the metal oxide atomic layer and the step of forming of the Si oxide atomic layer in an alternative manner.

3. The method of claim 2,
wherein the forming of the metal oxide atomic layer comprises:
supplying a metal source;
purging surplus of the metal source;
supplying a first reaction gas containing oxygen; and
purging surplus of the first reaction gas, and
wherein the forming of the Si oxide atomic layer comprises:
supplying a Si source;
purging surplus of the Si source;
supplying a second reaction gas containing oxygen; and
purging surplus of the second reaction gas.

4. The method of claim 2, wherein the metal oxide atomic layer satisfies a stoichiometry ratio.

5. The method of claim 1,
wherein the forming of the variable resistance layer comprises:
forming a metal oxide layer; and
exposing the metal oxide layer to a Si-containing gas.

6. The method of claim 5, wherein the forming of the metal oxide layer is performed by an ALD or a CVD (Chemical Vapor Deposition) method.

7. The method of claim 6, wherein the metal oxide layer satisfies a stoichiometry ratio.

8. The method of claim 1, further comprising:
performing a heat or plasma treatment in a gas atmosphere containing hydrogen after the forming of the variable resistance layer.

9. The method of claim 1, further comprising:
forming a metal oxide layer which is interposed between the first electrode and the variable resistance layer or between the second electrode and the variable resistance layer, wherein the metal oxide layer is configured to supply an oxygen vacancy to the variable resistance layer.

10. The method of claim 1, wherein the Si-added metal oxide comprises Si-added Ti oxide, Si-added Ta oxide, Si-added Fe oxide, Si-added W oxide, Si-added Hf oxide, Si-added Nb oxide, Si-added Zr oxide, Si-added Ni oxide, Si-added Al oxide, Si-added La oxide, Si-added Mg oxide, Si-added Sr—Ti oxide, or a combination thereof.

11. A method of fabricating a variable resistance memory device, comprising:
alternately stacking a plurality of interlayer insulating layers and a plurality of first patterns over a substrate;
forming a hole penetrating the alternately-stacked structure to expose sidewalls of the plurality of first patterns;
forming a variable resistance layer including Si-added metal oxide over a sidewall of the hole; and
forming a vertical electrode in the hole.

12. The method of claim 11,
wherein the forming of the variable resistance layer comprises:
forming a metal oxide atomic layer using ALD (Atomic Layer Deposition); and
forming a Si oxide atomic layer using ALD, and
repeating the forming of the metal oxide atomic layer and the forming of the Si oxide atomic layer in alternative manner.

13. The method of claim 12,
wherein the forming of the metal oxide atomic layer comprises:
supplying a metal source;
purging surplus of the metal source;
supplying a first reaction gas containing oxygen; and
purging surplus of the first reaction gas, and
wherein the forming of the Si oxide atomic layer comprises:
supplying a Si source;
purging surplus of the Si source;
supplying a second reaction gas containing oxygen; and
purging surplus of the second reaction gas.

14. The method of claim 12, wherein the metal oxide atomic layer satisfies a stoichiometry ratio.

15. The method of claim 11,
wherein the forming of the variable resistance layer comprises:
forming a metal oxide layer; and
exposing the metal oxide layer to a Si-containing gas.

16. The method of claim 15, wherein the forming of the metal oxide layer is performed by an ALD or a CVD method.

17. The method of claim 16, wherein the metal oxide layer satisfies a stoichiometry ratio.

18. The method of claim 11, the method further comprising:
performing a heat or plasma treatment to the variable resistance layer in a gas atmosphere containing hydrogen.

19. The method of claim 11, the method further comprising:
forming a metal oxide layer interposed between the first patterns and the variable resistance layer or between the vertical electrode and the variable resistance layer,
wherein the metal oxide layer is configured to supply an oxygen vacancy to the variable resistance layer.

20. The method of claim 11, wherein the Si-added metal oxide comprises Si-added Ti oxide, Si-added Ta oxide, Si-added Fe oxide, Si-added W oxide, Si-added Hf oxide, Si-added Nb oxide, Si-added Zr oxide, Si-added Ni oxide, Si-added Al oxide, Si-added La oxide, Si-added Mg oxide, Si-added Sr—Ti oxide, or a combination thereof.

21. The method of claim 11, the method further comprising:
forming a slit which penetrates the plurality of first patterns, after the forming of the vertical electrode;
removing the plurality of first patterns exposed by the slit; and
filling a conductive material in a space created by removing the plurality of first patterns, to form a plurality of horizontal electrodes, and
wherein each of the plurality of first patterns is a sacrificial pattern.

22. The method of claim 11, wherein each of the plurality of first patterns is a conductive layer.

23. The method of claim 11, the method further comprising:
forming a trench which extends in a first direction and exposes sidewalls of the plurality of first patterns by etching the alternately-stacked structure, before the forming of the hole; and
filling an insulating material in the trench, and
wherein the forming of the hole is performed by selectively etching the insulating material.
